(19) United States
(12) Patent Application Publication
(10) Pub. No.: US 2014/0118360 A1
(43) Pub. Date: May 1, 2014

(54) THINFILM STACKS FOR LIGHT MODULATING DISPLAYS

(71) Applicant: PIXTRONIX, INC., San Diego, CA (US)

(72) Inventors: Jian J. Ma, Carlsbad, CA (US); John H. Hong, San Clemente, CA (US); Tallis Y. Chang, San Diego, CA (US); Chong U. Lee, San Diego, CA (US)

(73) Assignee: PIXTRONIX, INC., San Diego, CA (US)

(21) Appl. No.: 13/664,276

(22) Filed: Oct. 30, 2012

(51) Int. Cl. H01L 33/60; H01L 33/08

(52) U.S. Cl. CPC H01L 33/60; H01L 33/08
USPC 345/501; 257/89; 438/29

(57) ABSTRACT

This disclosure provides systems, methods and apparatus for absorption film stacks. In one aspect, the absorption film stack is an interferometric absorption film stack that, for a selected wavelength of light, reduces light reflected from a surface of the stack by setting up a standing wave within the stack of materials. In some implementations, an absorbing layer may be placed at the peak of the standing wave interference pattern. The absorbing layer can be implemented to absorb selected wavelengths of light and substantially reduce the amount of unwanted reflections. In some other implementations, a reflective surface may be formed on the surface of the stack opposite the absorbing layer.

### TECHNICAL FIELD

This disclosure relates to the field of displays, and more particularly to displays that have a surface with integrally formed light modulators that pass or block light passing through the surface.

### DESCRIPTION OF THE RELATED TECHNOLOGY

In a conventional digital microelectromechanical shutter (DMS) display, a plurality of microelectromechanical systems (MEMS) shutters are fabricated on a surface of a substrate. The MEMS shutters are formed as a grid on the substrate and each MEMS shutter modulates light passing through an aperture formed proximate the shutter. To this end, each shutter is capable of blocking or passing light by moving over or away from the aperture and each shutter therefore forms a pixel or a portion of a pixel in the display. The operation of the shutters is controlled by a display controller which moves the shutters to block or pass light and thereby create an image on the display.

In this conventional design, the shutters are formed as assemblies that include the shutter, one or more electrodes for driving the shutter to open or close and other elements. These assemblies are formed on a substrate, typically an insulating material such as glass. Each assembly has a square peripheral edge and the shutter and other components of the assembly fit within the boundary of that peripheral edge. Typically, thousands of these assemblies are arranged in a two dimensional array, or grid, of rows and columns, thereby forming a display.

In operation, the shutters move over the aperture and when positioned over an aperture, the shutter blocks light passing through the aperture and traveling towards the surface of the display. By coding an image into data that directs certain shutters to be open and pass light and other shutters to be closed to block light, the grid of shutters can recreate the image on the display.

The ability of the display to produce an image and in particular to produce a sharply defined image turns, at least in part, on the ability of each shutter to modulate the amount of light that passes through the aperture and through the surface of the display. Specifically, the clarity of an image is improved when the shutters that are open pass light with minimal interference so that the open shutter is bright. Similarly, the clarity of an image is also improved when a shutter that is closed blocks light as fully as possible so that the closed shutter is as dark as possible. The ability to produce sharp images is enhanced when the difference in brightness between an open shutter and a closed shutter is large.

Although these displays work quite well, there remains a need to improve the contrast ratio of a displayed image, and in particular, there remains a need to improve the difference between the brightness of an open shutter and that of a closed shutter.

### SUMMARY

The systems, methods and devices of this disclosure each have several innovative aspects, no single one of which is solely responsible for the desirable attributes disclosed herein.

One innovative aspect of the subject matter described in this disclosure can be implemented in a device having a substrate layer disposed proximate a light source and having an aperture to allow light to pass through the substrate layer and an absorption film stack that includes a layer of light reflecting material, a layer of light absorbing material disposed on the layer of light reflecting material and being spaced a fixed distance from the layer of light reflecting material, and an interferometric absorption film stack, including a layer of a dielectric material of a first refractive index, and a layer of dielectric material of a second refractive index, the thicknesses of the layers of dielectric material being selected to cause light reflected from the interferometric absorption film stack to interfere with light incident on the interferometric absorption film stack and have an interference standing wave with a peak amplitude occurring at the layer of light absorbing material.

In some implementations, the device can include a layer of dielectric material of a first refractive index, and a layer of dielectric material of a second refractive index that are selected to reduce reflection of light incident at an angle between 0° and 50° to an axis normal to a surface of the interferometric absorption film stack.

In some implementations, the device can include a fixed distance that arranges the layer of absorbing material at a location of a substantially peak amplitude of the interference standing wave in the interferometric absorption film stack.

In some implementations, the device can include a layer of light reflecting material that includes a layer of metal having a reflectance greater than 70% through a spectrum for visible light. In some implementations, the device can include a transparent conductive layer disposed on the interferometric absorption film stack. In some implementations, the device can include a reflective film disposed on a surface of the layer of light reflecting material opposite the light absorbing material.

In some implementations, the device can include a reflective film having a dielectric thin film stack having a first material with a first refractive index and a second material with a second refractive index, the first material and the second material having a respective thickness of about a quarter wavelength of light from the light source.

In some implementations, the device can include a layer of fluid disposed over the interferometric absorption film stack.

In some implementations, the device can include a light source or plurality of light sources transmitting light at different wavelength spectrums centered respectively at colors red, green and blue (RGB).

In some implementations, the device can include a processor that is configured to communicate with the display, the processor being configured to process image data, and a memory device that is configured to communicate with the processor. In some implementations, the device can include a driver circuit configured to send at least one signal to the display, and a controller configured to send at least a portion of the image data to the driver circuit. In some implementations, the device can include an image source module configured to send the image data to the processor, wherein the image source module comprises at least one of a receiver, transceiver, and transmitter. In some implementations, the device can include an input device configured to receive input data and to communicate the input data to the processor.

Another innovative aspect of the subject matter described in this disclosure can be implemented in a method of manufacturing, including providing a layer of light reflecting material, and forming over the layer of light reflecting material, a light absorbing film having a layer of light absorbing material, and a first layer of material with a first index of refraction and a first thickness of about 25 to 40 nm and a second layer of material with a second index of refraction and a second thickness of about 10 nm to 20 nm, the respective thicknesses of the first and second layers being selected to provide interferometric attenuation of light within a selected range of wavelengths and at an angle of incidence more than about 30° to an axis normal to the absorbing film.

In some implementations, the method can include arranging the layer of absorbing material at a location of a substantially peak amplitude of a standing wave formed by the interferometric attenuation.

In some implementations, the method can include providing a spacing layer of transmissive material between the light reflecting layer and the layer of absorbing material and having a thickness selected to space the layer of absorbing material from the light reflecting layer about a quarter wavelength of light reflected from the light reflecting layer.

In some implementations, the method can include forming between the substrate and the light absorbing film, a film stack having a first material with a first refractive index and a second material with a second refractive index, the first material and the second material having respective thicknesses of about a quarter wavelength of light to be reflected. In some implementations, the first material has a thickness of between about 80 nm to about 100 nm, and the second material has a thickness of between about 50 nm and about 65 nm. In some implementations, the first material includes silicon dioxide (SiO₂) and the second material includes titanium dioxide (TiO₂).

In some implementations, the layer of light reflecting material is a layer of metal. Forming the first layer of material can include depositing the first layer using one or more of the following processes: chemical vapor deposition, physical vapor deposition, plasma-enhanced chemical vapor deposition, thermal chemical vapor deposition (i.e., thermal CVD), and spin-coating. In some implementations, providing a layer of light reflecting material includes providing a shutter movable from a first position to a second position and having a surface with a layer of light reflecting material. In some implementations, forming the light absorbing film includes forming the light absorbing film over the layer of the light reflecting material of the shutter.

Another innovative aspect of the subject matter described in this disclosure can be implemented in a thin film stack, including a substrate layer having an aperture to allow light to pass through the substrate layer and being disposed proximate a light source of a first wavelength, and including a layer of light reflecting material having a first side and a second side, an interferometric absorption stack disposed on the second side of the layer of light reflecting material and having two layers of dielectric material with thicknesses and refractive indices selected to reduce a reflectivity of light incident at angles 0° to 50° and propagating at the first wavelength, and a high reflectance stack disposed on the first side of the layer of light reflecting material and having one or more than one paired layers of dielectric material with thicknesses and refractive indices selected to achieve photopically weighted reflectivity of greater than 70%, or greater than 90% for light incident at angles between 0° to 50° and propagating at the first wavelength.

In some implementations, the substrate layer includes a layer of photopically transparent material. In some implementations, a shutter can be disposed proximate the aperture and movable across the aperture for passing and blocking light emanating through the aperture. In some implementations, the light emanating through the aperture can form a portion of an image in a pixel.

In some implementations, the light source includes a plurality of light sources generating light at different respective wavelengths. In some implementations, the interferometric absorption stack includes two layers of dielectric material with thicknesses and refractive indices selected to reduce a photopically weighted reflectivity of light propagating at the different respective wavelengths. In some implementations, the high reflectance stack includes one or more paired layers of dielectric material with thicknesses and refractive indices selected to achieve a photopically weighted reflectivity of at least 70% and often greater than 95% for light propagating at the different respective wavelengths.

Details of one or more implementations of the subject matter described in this disclosure are set forth in the accompanying drawings and the description below. Although the examples provided in this disclosure are primarily described in terms of electromechanical systems (EMS) and microelectromechanical systems (MEMS)-based displays the concepts provided herein may apply to other types of displays such as liquid crystal displays (LCDs), organic light-emitting diode (“OLED”) displays, and field emission displays. Other features, aspects, and advantages will become apparent from the description, the drawings and the claims. Note that the relative dimensions of the following figures may not be drawn to scale.

### BRIEF DESCRIPTION OF THE DRAWINGS

FIG. 1 is a plan view of an example display apparatus.

FIG. 2 is an illustrative shutter-based light modulator suitable for incorporation into the MEMS-based display of FIG. 1.

FIG. 3 is a schematic cut away view illustrating light passing to shutter assemblies such as the shutter assemblies of FIG. 2.

FIG. 4 is a pictorial representation of one film stack suitable for use on the surface of a display.

FIG. 5 is a graphical illustration of the wavelengths of light generated by a light source having plural different sources.

FIGS. 6A, 6B and 6C are pictorial representations of the light incident and reflected from an interferometric absorbing layer.

FIGS. 7A and 7B are graphical representations of the reflectivity spectrum and photopically weighted reflectivity of a film stack of the type shown in FIG. 4.

FIGS. 8A and 8B are two examples of film stacks having high reflectivity.

FIG. 9 is a graphical illustration of the angular distribution of a high reflectivity film such as the film of FIG. 8A.

FIGS. 10A and 10B are examples of a display device and controller of the type suitable for use with the displays described herein.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device, apparatus, or system that can be configured to display an image, whether in motion (such as video) or stationary (such as still images), and whether textual, graphical or pictorial. More particularly, it is contemplated that the described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, global positioning system (GPS) receivers/navigators, cameras, digital media players (such as MP3 players), camcorders, game consoles, wrist watches, clocks, calculators, television monitors, flat panel displays, electronic reading devices (e.g., e-readers), computer monitors, auto displays (including odometer and speedometer displays, etc.), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS) applications including microelectromechanical systems (MEMS) applications, as well as non-EMS applications), aesthetic structures (such as display of images on a piece of jewelry or clothing) and a variety of EMS devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

The systems and methods described herein include, among other things, a display that has substrate which carries or otherwise supports light modulating elements. The light modulating elements will modulate light, typically by either fully passing or fully blocking light from a light source, to modulate between a fully illuminated state and a fully darkened state, although in some implementations intermediate levels of illumination may be achieved. By modulating light, an image can be generated on the display. The quality of the image depends, in part, on the contrast ratio for the image. The contrast ratio can be negatively affected by light reflecting off the surface of the substrate. In some implementations, the surface of the substrate includes an interferometric absorption film stack that, for a selected wavelength or wavelengths of light, reduces light reflected from the surface of the stack.

In some implementations, the interferometric absorption film stack controls how light is reflected from the surface of the stack to cause destructive interference between the reflected light and the incident light. Typically, the destructive interference sets up a standing wave within the stack of materials. By placing an absorbing material at the peak, or substantially the peak, of the standing wave interference pattern, the absorbing material attenuates the power of the reflected light and further reduces the amount of unwanted reflection.

In some implementations, the absorption film stack can include a reflecting layer, a spacer, an absorbing layer, two layers of dielectric material arranged as a pair of layers having different indices of refraction, and an optional transparent conductive layer as the outside layer for dissipating static charges. The thicknesses, indices of refraction and refractive index dispersion properties of the paired layers may be selected to reduce the reflectivity of light traveling at angles typical of scattered and unwanted reflections; the type of light that can reduce contrast ratio of the image. The thicknesses, indices of refraction and refractive index dispersion properties of the paired layers also may be selected to reduce reflection of light within the spectrum of visible light, or at least a broad portion of that spectrum, and generated by a light source illuminating the display.

Additionally, in some implementations, the surface of the substrate has a side that faces the light source. For this side, the substrate may have a highly reflective surface. In these implementations, the highly reflective surface can share the same reflecting layer of the absorption film stack and can include a high reflectance stack having two or more layers of dielectric material with thicknesses and refractive indices selected to achieve the photopically weighted reflectivity of greater than 70%, greater than 90%, and even greater than 95% for light incident on to the surface and propagating at the wavelength or wavelengths of the light source.

Particular implementations of the subject matter described in this disclosure can be implemented to realize one or more of the following potential advantages. By sharing the reflective layer, the fabrication process may, advantageously, eliminate a metallization stage during manufacture. As such, in some implementations, the thicknesses of the layers are selected to reduce photopically weighted reflectivity based on the power spectrum of the light source and the angular distribution of unwanted light. A photopically weighted reflectivity is a measure of reflectivity that weights reflected light according to a photopic luminosity function, such as the 1931 CIE photopic luminosity function, that describes the average spectral sensitivity of human visual perception. In some implementations, the index of refractions and the thickness of the layers in the stack are selected to minimize the photopically weighted reflectivity according to the power spectrum of the light source and the angular distribution of the unwanted light, which is typically less than 45°. The unreflected light is absorbed by the absorbing layer, which may be a metal layer that absorbs light passing through that layer. This can reduce unwanted reflection and improve contrast ratio.

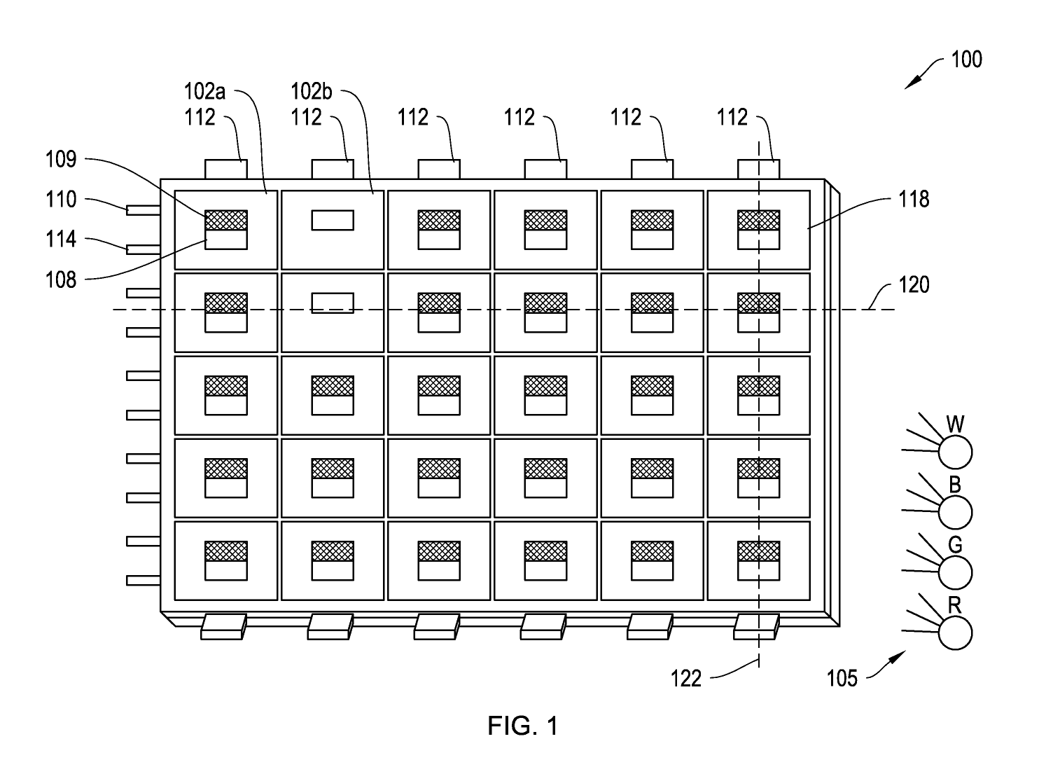

FIG. 1 is a plan view of an example display apparatus 100. A MEMS-based display apparatus is an example of the type of display according to the systems and methods described herein. However, the display apparatus 100 is only an example and many other displays, including non-MEMS displays, such as LCD, OLED, electrowetting displays or other display types, may be realized using the systems and methods described herein.

The depicted display apparatus 100 includes a plurality of light modulators 102 (generally “light modulators 102”) arranged in rows 120 and columns 122. In the display apparatus 100, the light modulator 102a is in the open state, allowing light to pass through aperture 109. Light modulator 102b is in the closed state, obstructing the passage of light. By selectively setting the states of the light modulators 102, the display apparatus 100 can be utilized to form an image for a backlit display, if illuminated by a lamp or lamps 105. In another implementation, the apparatus 100 may form an image by reflection of ambient light originating from the front of the apparatus. In yet another implementation, the apparatus 100 may form an image by reflection of light from a lamp or lamps positioned in the front of the display, i.e. by use of a frontlight. In one of the closed or open states, the light modulators 102 interfere with light in an optical path by, for example, and without limitation, blocking, reflecting, absorbing, filtering, polarizing, diffracting, or otherwise altering a property or path of the light.

In the display apparatus 100, each light modulator 102 corresponds to a pixel in an image. In other implementations, the display apparatus 100 may utilize a plurality of light modulators 102 to form a pixel in an image. For example, the display apparatus 100 may include three color-specific light modulators 102. By selectively opening one or more of the color-specific light modulators 102 corresponding to a particular pixel, the display apparatus 100 can generate a color pixel in an image. In another example, the display apparatus 100 includes two or more light modulators 102 per pixel to provide grayscale in an image. With respect to an image, a “pixel” corresponds to the smallest picture element defined by the resolution of the image. With respect to structural components of the display apparatus 100, the term “pixel” refers to the combined mechanical and electrical components utilized to modulate the light that forms a single pixel of the image.

Further, it is noted that the depicted display apparatus 100 is a direct-view display in that it does not require imaging optics. The user sees an image by looking directly at the display apparatus 100. In alternate implementations the display apparatus 100 is incorporated into a projection display. In such implementations, the display forms an image by projecting light onto a screen or onto a wall. Direct-view displays may operate in either a transmissive or reflective mode. In a transmissive display, the light modulators filter or selectively block light which originates from a lamp or lamps positioned behind the display. The light from the lamps is optionally injected into a light guide or “backlight.” Transmissive direct-view display implementations may be often built onto transparent or glass substrates to facilitate an assembly arrangement where one substrate, containing the light modulators, is positioned directly on top of the backlight. In some transmissive display implementations, a color-specific light modulator is created by associating a color filter material with each light modulator 102. In other transmissive display implementations colors can be generated using a field sequential color method by alternating illumination of lamps with different primary colors.

Each light modulator 102 includes a shutter 108 and an aperture 109. To illuminate a pixel in an image, the shutter 108 is positioned such that it allows light to pass through the aperture 109 towards a viewer. To keep a pixel unlit, the shutter 108 is positioned such that it obstructs the passage of light through the aperture 109. The aperture 109 in the depicted example is defined by an opening patterned through a reflective or light-absorbing material.

The display apparatus also includes a control matrix connected to the substrate and to the light modulators for controlling the movement of the shutters. The control matrix includes a series of electrical interconnects (e.g., interconnects 110, 112, and 114), including at least one write-enable interconnect 110 (also referred to as a “scan-line interconnect”) per row of pixels, one data interconnect 112 for each column of pixels, and one common interconnect 114 providing a common voltage to all pixels, or at least to pixels from both multiple columns and multiples rows in the display apparatus 100. In response to the application of an appropriate voltage (the “write-enabling voltage, V_{we}”), the write-enable interconnect 110 for a given row of pixels prepares the pixels in the row to accept new shutter movement instructions. The data interconnects 112 communicate the new movement instructions in the form of data voltage pulses. The data voltage pulses applied to the data interconnects 112, in some implementations, directly contribute to an electrostatic movement of the shutters. In other implementations, the data voltage pulses control switches, such as transistors or other non-linear circuit elements that control the application of separate actuation voltages, which are typically higher in magnitude than the data voltages, to the light modulators 102. The application of these actuation voltages then results in the electrostatic driven movement of the shutters 108, moving the shutters 108 from a first position to a second position. In some implementations, this moves a shutter 108 from an open position to a closed position. But in some other implementations, the actuation voltage may drive the shutter between first and second positions that are intermediate between open and closed.

In some cases, a dual set of “open” and “closed” actuators may be provided as part of a shutter assembly so that the control electronics are capable of electrostatically driving the shutters into each of the open and closed states.

Display apparatus 100, in alternative implementations, includes light modulators other than transverse shutter-based light modulators. For example, an alternative implementation may include a rolling actuator shutter-based light modulator suitable for incorporation into an alternative implementation of the MEMS-based display apparatus 100 of FIG. 1. It will be understood that still other MEMS light modulators are known and can be usefully incorporated into the implementations described herein. Similarly, other types of shutter control systems may be employed with the display described herein including methods by which an array of shutters can be controlled via a control matrix to produce images, in many cases moving images, with appropriate gray scale. In some cases, control is accomplished by means of a passive matrix array of row and column interconnects connected to driver circuits on the periphery of the display. In other cases it is appropriate to include switching and/or data storage elements within each pixel of the array (the so-called active matrix) to improve either the speed, the gray scale and/or the power dissipation performance of the display. Any of these control systems may be employed with the systems and methods described herein.

The shutter assemblies 102 have a peripheral surface 118 shown in FIG. 1 as a rectangular peripheral surface that surrounds the shutter 108 and the aperture 109. In one implementation, the peripheral surface 118 of each shutter assembly 102 includes a light absorbing layer that reduces the intensity of light reflected off the surface 118. In one implementation, the light absorbing layer 118 includes a plurality of films that are formed as a stack of films on the base or substrate that supports the display 100. Typically, the stack of film material is formed by a semiconductor manufacturing process during the formation of the shutter assemblies 102 which, in this implementation, are MEMS shutter assemblies typically formed through lithographic fabrication processes.

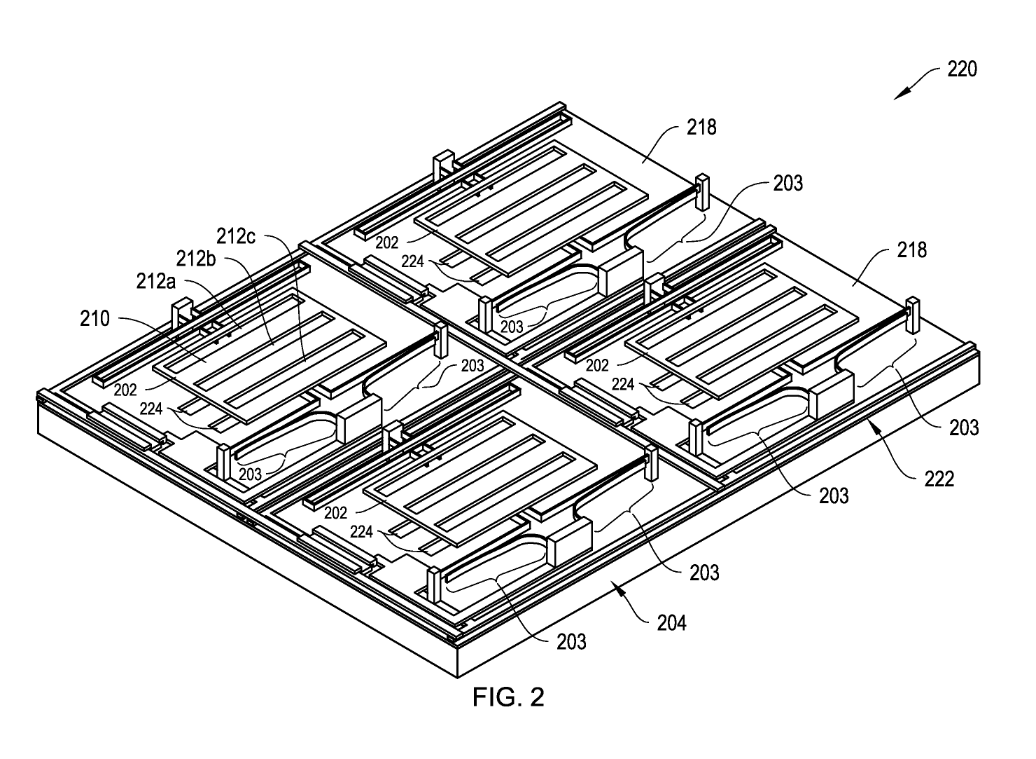

FIG. 2 is an illustrative shutter-based light modulator suitable for incorporation into the MEMS-based display of FIG. 1. FIG. 2 depicts in more detail an example of lithographically formed shutter assemblies such as the shutter assemblies 102 depicted in FIG. 1. In particular, FIG. 2 depicts an array 220 of four shutter assemblies 202. Each of the shutter assemblies includes a shutter 210 that has three slots 212A, 212B and 212C and a plurality of apertures 224 that are formed in an aperture layer 222 that is formed on a substrate 204. One or more actuators 203 drive a shutter 210 to align the slots 212 of the shutter 210 relative to the apertures 224. The array 220 further includes a surface 212 that includes a light absorbing material carried on the aperture layer 222. In some implementations, the surface 212 is formed as a stack of thin films deposited on the substrate 204 optionally during the manufacture of the shutter assemblies 202 of array 220.

The shutters 210 are movable and may be aligned over the apertures 224 to align a slot over an aperture or to align the shutter 210 to block light passing from the aperture. In one implementation the substrate 204 is made of a transparent material, such as glass or plastic or some other material that passes light in the visible spectrum. In another implementation the substrate 204 is made of an opaque material, and holes are etched in the substrate to form the apertures 224.

The shutter assemblies 202 are fabricated using techniques similar to the art of micromachining or from the manufacture of micromechanical (i.e., MEMS) devices. For instance the shutter assembly 202 can be formed from thin films of amorphous silicon, deposited by a chemical vapor deposition process.

In some optional implementations, the shutter assembly 202 together with the actuator 203 can be made bi-stable. That is, the shutters can exist in at least two equilibrium positions (e.g., open or closed) with little or no power required to hold them in either position. More particularly, the shutter assembly 202 can be mechanically bi-stable. Once the shutter of the shutter assembly 202 is set in position, no electrical energy or holding voltage is required to maintain that position. The mechanical stresses on the physical elements of the shutter assembly 202 can hold the shutter in place.

Further optionally, the shutter assembly 202 together with the actuator 203 can be made electrically bi-stable. In an electrically bi-stable shutter assembly, there exists a range of voltages below the actuation voltage of the shutter assembly, which if applied to a closed actuator (with the shutter being either open or closed), holds the actuator closed and the shutter in position, even if an opposing force is exerted on the shutter. The opposing force may be exerted by a spring such as spring 207 in shutter-based light modulator 202, or the opposing force may be exerted by an opposing actuator, such as an “open” or “closed” actuator.

The light modulator array 220 is depicted as having a single MEMS light modulator per pixel. Other implementations are possible in which multiple MEMS light modulators are provided in each pixel, thereby providing the possibility of more than just binary “on” or “off” optical states in each pixel. Certain forms of coded area division gray scale are possible where multiple MEMS light modulators in the pixel are provided, and where apertures 224, which are associated with each of the light modulators, have unequal areas.

The surface of the array 220 may include a light absorbing layer 218 that reduces the intensity of light, typically photopic light, reflected off the surface 218 of the array 220. FIG. 2 illustrates that by reducing reflections off the surface 218, the contrast between an open shutter and the background will improve.

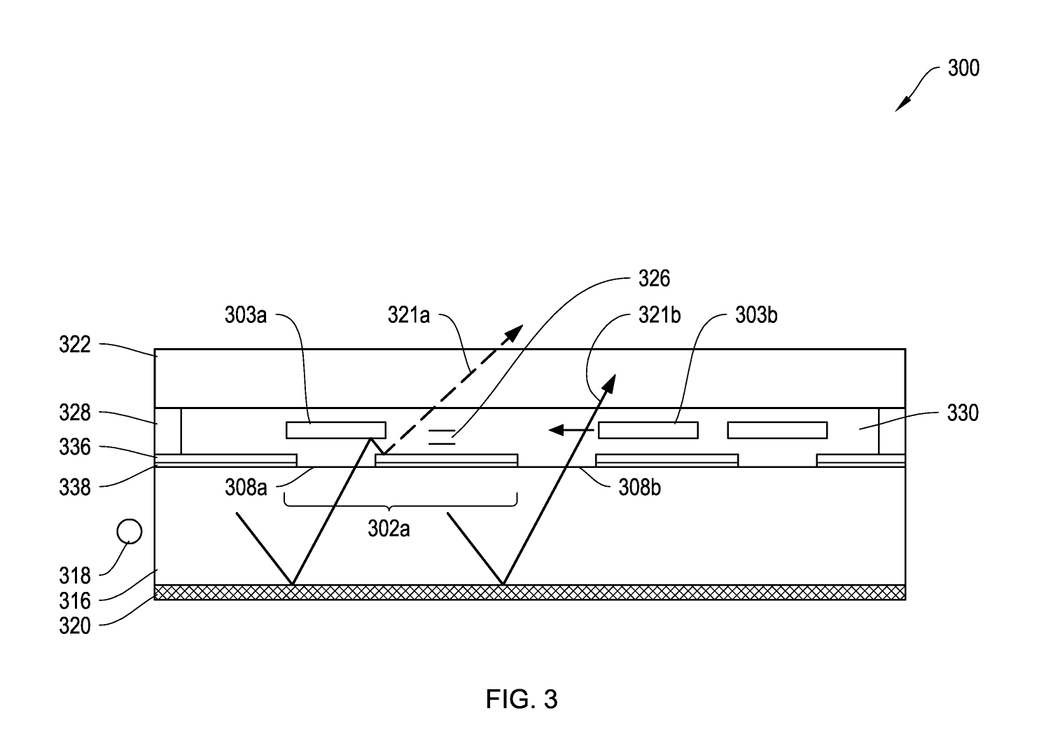

FIG. 3 is a schematic cut away view illustrating light passing to shutter assemblies such as the shutter assemblies of FIG. 2. FIG. 3 shows pictorially the action of the light absorbing surface 218 of the shutter assemblies 220 for reducing light reflected from the surface of the shutter assemblies 220. In particular, FIG. 3 depicts a cut-away pictorial view of a display 300 that includes a plurality of shutter assemblies 302 that include a shutter 303 that can move over and away from an aperture 308 for the purpose of modulating the luminance of light passing through a respective aperture 308. That is, the shutters 303 by blocking or passing light traveling through the aperture 308 modulate, or change, the luminance of a particular pixel within an image. The contrast ratio, as measured between the luminance of a pixel when the shutter is open versus the luminance of that same pixel when the shutter is closed, represents a measure of how clearly an image can be presented on the display. The effectiveness of the shutters at blocking light passing through an aperture determines, at least in part, the contrast ratio for the display 300.

FIG. 3 depicts in more detail how a shutter 303 moves across an aperture 308 to modulate light passing through the aperture 308 and how light passing under a closed shutter 303 may reduce image clarity by reflecting off the surface of the shutter assemblies 302. In particular FIG. 3 depicts display 300 that includes shutters 303 that move over apertures 308 to block light such as the light rays 321A and 321B generated from the light source 318. The light source 318 directs light into the light guide 316 which guides light underneath the surface of the shutter assemblies 302. A reflective surface 320 reflects light upward towards the apertures 308 for modulation by the shutters 303. The cover plate 322 is arranged against one side of the shutter assemblies 302.

FIG. 3 depicts shutter 303A as being disposed over an aperture 308A. FIG. 3 also depicts shutter 303B as being spaced away from aperture 308B so that light from the light source 318 can pass from the light guide 316 through the aperture 308B and through the cover plate 322. FIG. 3 depicts the shutter 303B in an open position and the shutter 303A in a closed position. The shutter 303A in the closed position should block light from light source 318 from passing through the aperture 308A and onward through the cover plate 322. However, FIG. 3 depicts that even in a closed position, light at a certain angle may pass through the aperture 308A and through the gap 326 that exists between the closed shutter 303A and the lower surface of the shutter assembly 302A. Light passing through an aperture, such as aperture 308A, that has been closed by a shutter 303A reduces the effectiveness of that respective shutter 303A for modulating the amount of light that will pass through the aperture 308A when the shutter is in the open position and the closed position. The gap 326 depicted in FIG. 3 allows light that is at a sufficiently high angle to reflect off the surface of the shutter 303A facing the light source and reflect again off the opposite surface of the shutter assembly 302A. In the depicted example, light traveling at an angle of 30° to 50°, or perhaps 0° to 50°, relative to the horizontal surface of the shutter 303, may avoid being blocked by the shutter 303A, and escape through gap 326. Light 321A that travels through gap 326 may reduce the contrast ratio between the luminance of a closed shutter and the luminance of an open shutter.

To address this, the surface of the shutter assembly 302 may include a light absorbing stack 336 of thin films deposited on the substrate 338 optionally during the manufacture of the shutter assemblies 302. The light absorbing stack 336 may reduce the amount of light reflected off the shutter assembly 302, and in particular may reduce light incident on the shutter assembly 302 at angles between 30° to 50°, or perhaps 0° to 50°, or at other angles expected for light passing through gap 326. Thus, in some implementations, the light absorbing stack 336 may reduce reflections of such low angle escaping light, as the angles may be measured relative to an axis normal to the horizontal upper surface of the depicted stack 336. Additionally, in some implementations, the light absorbing stack 336 reduces light at wavelengths of the light source 318. Thus, the light absorbing stack 336 may, in some examples, be tuned to reduce light at the angles and wavelengths of light passing through gap 326.

It can be seen from FIG. 3 that in certain optional implementations, the cover plate 322 is sealed by seal 328 to provide a fluid-tight chamber between the cover plate 322 and the substrate 338. The seal 328 retains a working fluid 330 within the chamber. The working fluid 330 may have viscosities that may be below about 10 centipoise and with relative dielectric constant that may be above about 2.0, and dielectric breakdown strengths above about 10⁴ V/cm. The working fluid 330 can serve as a lubricant. In some implementations, the working fluid 330 is a hydrophobic liquid with a high surface wetting capability. In one particular implementation, the working fluid 330 has an index of refraction n of about 1.38. But other fluids with other indices of refraction and other optical properties may be employed with the systems and methods described herein. The reflective index of the fluid may affect the interference property of the light absorbing stack 336 and typically is included in the design of the light absorbing stack 336 to reduce or substantially minimize the photopically weighted reflection.

Suitable working fluids 330 include, without limitation, de-ionized water, methanol, ethanol and other alcohols, paraffins, olefins, ethers, silicone oils, fluorinated silicone oils, or other natural or synthetic solvents or lubricants. Useful working fluids can be polydimethylsiloxanes, such as hexamethyldisiloxane and octamethyltrisiloxane, or alkyl methyl siloxanes such as hexylpentamethyldisiloxane. Useful working fluids can be alkanes, such as octane or decane. Useful fluids can be nitroalkanes, such as nitromethane. Useful fluids can be aromatic compounds, such as toluene or diethylbenzene. Useful fluids can be ketones, such as butanone or methyl isobutyl ketone. Useful fluids can be chlorocarbons, such as chlorobenzene. Useful fluids can be chlorofluorocarbons, such as dichlorofluoroethane or chlorotrifluoroethylene. And other fluids considered for these display assemblies include butyl acetate, dimethylformamide.

For many implementations, it is advantageous to incorporate a mixture of the above fluids. For instance mixtures of alkanes or mixtures of polydimethylsiloxanes can be useful where the mixture includes molecules with a range of molecular weights. It is also possible to optimize properties by mixing fluids from different families or fluids with different properties. For instance, the surface wetting properties of a hexamethyldisiloxane can be combined with the low viscosity of butanone to create an improved fluid.

As noted above, to reduce unwanted reflection of light from the surface 336 of the shutter assembly 302, the surface 336 may include a light absorbing stack of thin films deposited on the substrate 338. The systems and methods described herein provide an interferometric absorption film, an absorption film stack, that in some implementations, for a selected wavelength of light, absorb reflected light by setting up a standing wave within a stack of materials and by placing a thin absorbing layer at the peak of the standing wave interference pattern. Typically, a thin absorbing layer has a thickness ranging between several nanometers to tens of nanometers and can be 10-500 nm or more particularly between about 10-100 nm. However, the thickness of the absorbing layer may vary depending upon the material employed and the amount of absorption to be achieved and any suitable thickness may be used. This absorption film stack is understood to attenuate the power of the reflected light and substantially reduce the amount of reflection from the surface of the shutter assembly 302.

In some implementations, the absorption film stack is composed of a metal reflective layer (such as aluminum (Al)), a dielectric spacer (such as silicon dioxide (SiO₂)), an absorbing layer (such as molybdenum chromium (MoCr)), a pair of high/low refractive index matching layers (such as titanium dioxide/silicon dioxide (TiO₂/SiO₂)), and a thin transparent conductive layer (such as indium tin oxide (ITO)) as the most outside layer for dissipating static charges.

The thicknesses of the layers may be selected to achieve a selected, in some cases preferably minimal, photopically weighted reflectivity based on the power spectrum of the light source and the angular distribution of the unwanted reflected light. Specifically, the index of refractions and the thickness of the layers in the stack are selected to set up a standing wave within the stack of materials and form destructive interference among the light reflected from the stack layers within the power spectrum of the light source and the angular distribution of the unwanted leakage light, which is typically less than 45°. The unreflected light is mostly absorbed by the absorbing layer.

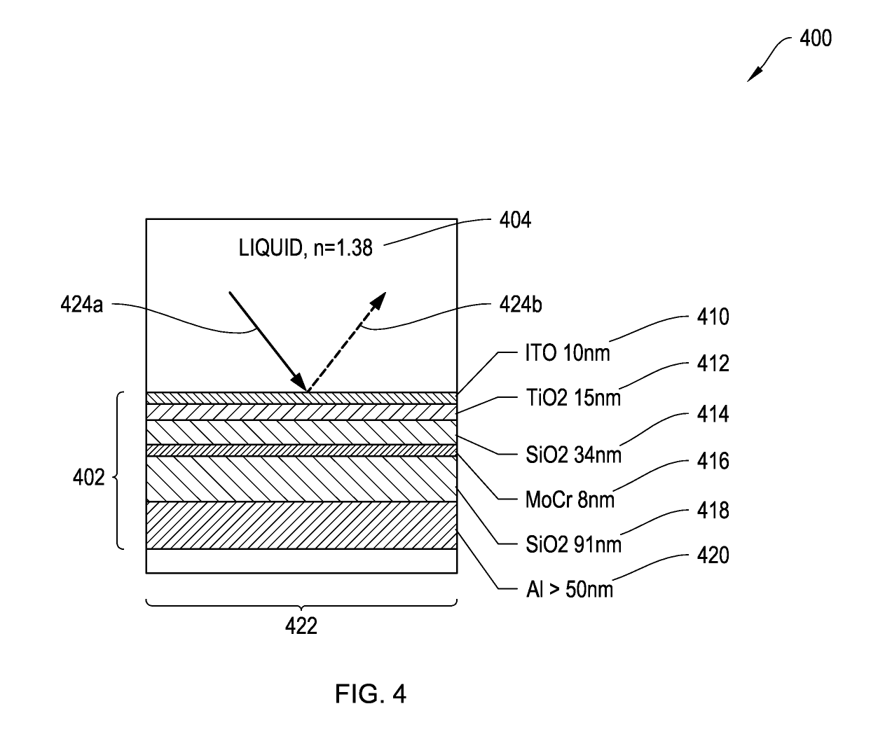

FIG. 4 is a pictorial representation of one film stack suitable for use on the surface of a display. FIG. 4 depicts an example that has an interferometric absorption film stack. In particular, FIG. 4 depicts a portion 400 of a display, such as the displays depicted in FIGS. 1 and 2, that includes a film stack 402, an optional liquid lubricant 404 and a substrate 422. The depicted optional liquid lubricant 404 is transparent or substantially photopically transparent, wherein photopically will be understood as being associated with the brightness of the wavelengths perceived by the average human eye, and will have an index of refraction that may be different from the index of refraction for air. In FIG. 4, a light ray 424A is depicted as being incident against the film stack 402 and a reflected ray 424B reflects off the surface of the stack 402. The reflected ray 424B is shown as a dash line to indicate the reflected ray 424B has reduced power compared to the incident ray 424A.

The film stack 402 is disposed on a substrate 422 which can be any suitable substrate for supporting a thin film stack, such as those described herein, and typically will include substrates such as the substrate 204 depicted in FIG. 2 upon which the shutter assemblies 202 are formed through semiconductor manufacturing techniques. The depicted film stack 402 has a light reflecting metal layer 420 that can reflect light, in particular photopically detectable light. In the depicted film stack 402 the light reflecting metal material is aluminum (Al) and is shown as having a thickness of about, or greater than, 50 nm. In other implementations the thickness of the reflecting metal layer 420 may be between 15 and 150 nm thick, or between 35 and 65 nm thick, or between 49 and 51 nm thick. The thickness of this layer 420 may vary to address the application, the type of material employed as a reflecting material, which in some implementations is metal, but in other implementations may be a metal composite or other material, and as a result in variations of the employed deposition techniques. The film stack 402 further includes a layer of light absorbing material 416, that is spaced a distance above the light reflecting metal layer 420. To this end, the film stack 402 includes a spacing layer 418 of a transparent, or substantially transparent, material that is disposed between the light reflecting metal layer 420 and the layer of absorbing material 416. In the depicted implementation the spacing layer 418 includes a SiO₂ layer that is, in this example, 91 nm in thickness. In some other implementations, the thickness of the spacing layer 418 may be between 30 and 300 nm thick, or between 60 and 120 nm thick, or between 89 and 93 nm thick. The thickness of this layer 418 may vary to address the application, the wavelength or wavelengths of light being reflected, and as a result in variations of the employed deposition techniques.

Disposed on the light absorbing layer 416 is a pair of dielectric materials 412 and 414. In the depicted implementation the dielectric pair includes a layer of TiO₂ that is approximately 15 nm thick, and in other implementations may be between 5 and 45 nm thick, or between 10 and 20 nm thick, or between 13 and 17 nm thick and a layer of SiO₂ that is approximately 34 nm thick, and in other implementations may be between 10 and 100 nm thick, or between 20 and 45 nm thick, or between 29 and 40 nm thick. The thickness of these layers may vary to address the application, the wavelengths being reflected, and as a result in variations of the employed deposition techniques. The depicted film stack 402 further includes an optional conductive layer 410 that, for this example, includes a layer of ITO of approximately 10 nm in thickness. In other implementations the conductive layer 410 may be between 3 and 30 nm thick, or between 7 and 13 nm thick, or between 9 and 11 nm thick. The thickness of this layer 410 may vary to address the application, the expected charge on the surface, the wavelengths being reflected, and as a result in variations of the employed deposition techniques.

In the depicted implementation, the film stack 402 is covered by a liquid having a characteristic average index of refraction n, over the spectrum of visible wavelengths, that in this case n=1.38. The thickness of the thin films in the stack 402 are selected for a liquid of n=1.38 to reduce and substantially minimize the photopically weighted reflection. However, the use of liquid is optional and in some other implementations, the shutters are in a non-liquid filled environment, such as an air or other gas environment, or in a vacuum. Additionally, those implementations that place the shutters in a liquid environment typically use a liquid that reduces stiction of moving parts. The type of liquid and the index of refraction of the liquid may vary, and any suitable liquid may be used. In some implementations, the liquid is deionized water, silicone oil or ethanol, but other liquids may be employed.

As noted above, the film stack 402 includes a light reflecting metal layer 420 of aluminum, a spacing layer 418 of SiO₂, a light absorbing layer 416 of MoCr, a pair of high/low refractive index matching layers of TiO₂/SiO₂, and an optional transparent conductive layer 410 of ITO. This conductive layer can be used to help dissipate static charges on the surface.

The paired materials TiO₂ and SiO₂ are generally photopically transparent materials. Both materials have a dispersion characteristic of index of refraction and the index of refraction of the two materials and their dispersion properties are different. SiO₂ has an average refractive index, n, of about 1.5 over the visible spectrum. TiO₂ has an average refractive index, n, of about 2.5 over the visible spectrum. In some other implementations, the refractive indices may vary, and the indices typically vary as a function of the conditions of film deposition. As noted above, the indices of refraction of a material also typically vary as a function of the wavelength of light passing through the material. Layering the materials over each other, in selected thicknesses, and optionally doing so in multiple pairs, introduces a desired phase shift to light passing through the absorption film stack. For the absorption film stack 402 to interferometrically reduce reflectivity, the phase shift is selected to achieve an impedance match, typically to substantially optimize the impedance match for a broad range of wavelengths in the visible spectrum band. At the location of substantially the peak intensity of the light wave passing through the stack 402, the light absorbing layer 416 of the stack 402 is disposed. The result is that the overall reflectivity of light 424B from the absorption film stack 402 is substantially reduced.

Optionally, film thicknesses are selected that can be deposited with sufficient precision to reliably achieve tolerances of +/−5% and perhaps +/−2.5% or less. Achieving such tolerances reduces variation in reflectivity, which can arise if layers too thick or too thin are formed to achieve a phase shift that causes destructive interference. The Table 1 below presents example film thicknesses given in nanometers.

TABLE 1

| | | Thickness, |
|---|---|---|
| Layer # | material | nm |
| 1 | Al | >50 |
| 2 | SiO2 | 91.1 |
| 3 | MoCr | 7.74 |
| 4 | SiO2 | 33.7 |
| 5 | TiO2 | 15.1 |
| 6 | ITO | 10.0 |

It will be understood that the thicknesses presented in Table 1 are only exemplary and that in other implementations, different materials and different thicknesses may be employed. Additionally, variations in thicknesses can exist, including as much as +/−10%, or +/−5% or +/−2.5%, while still producing beneficial results. For example, the absorbing layer may be any suitable material that will absorb the power of the light and may include, for example, molybdenum (Mo), Mo alloy, Al, Al alloy, chromium (Cr), vanadium (V), germanium (Ge) or other light absorbing materials. The light reflecting material in the example above is aluminum, and may be any suitable material for reflecting light. Typically the reflecting metal layer is a metal material that is a high reflectance material having a reflectance of for example 70% or greater, or more typically 90% or greater and that reflects visible light, and is formed in a layer sufficiently thick to achieve substantial reflectance and may for example be a light-reflective metal, such as Mo, Mo alloy, Al, Al alloy, Cr, nickel (Ni), titanium (Ti), tantalum (Ta), or silver (Ag) or combinations thereof.

The depicted layers 412 and 414 are typically dielectric materials having different dispersion characteristics of index of refraction, and the thicknesses of the two layers 412 and 414 of dielectric material are selected to achieve a reduced, typically a substantially minimal, photopically weighted reflection. Other high reflective index high dispersion materials, such as zirconium dioxide (ZrO₂), silicon nitride (Si₃N₄) can be used to replace the TiO₂. Likewise, other low refractive index low dispersion materials, such as magnesium fluoride (MgF₂), and aluminum oxide (Al₂O₃) can be used to replace SiO₂.

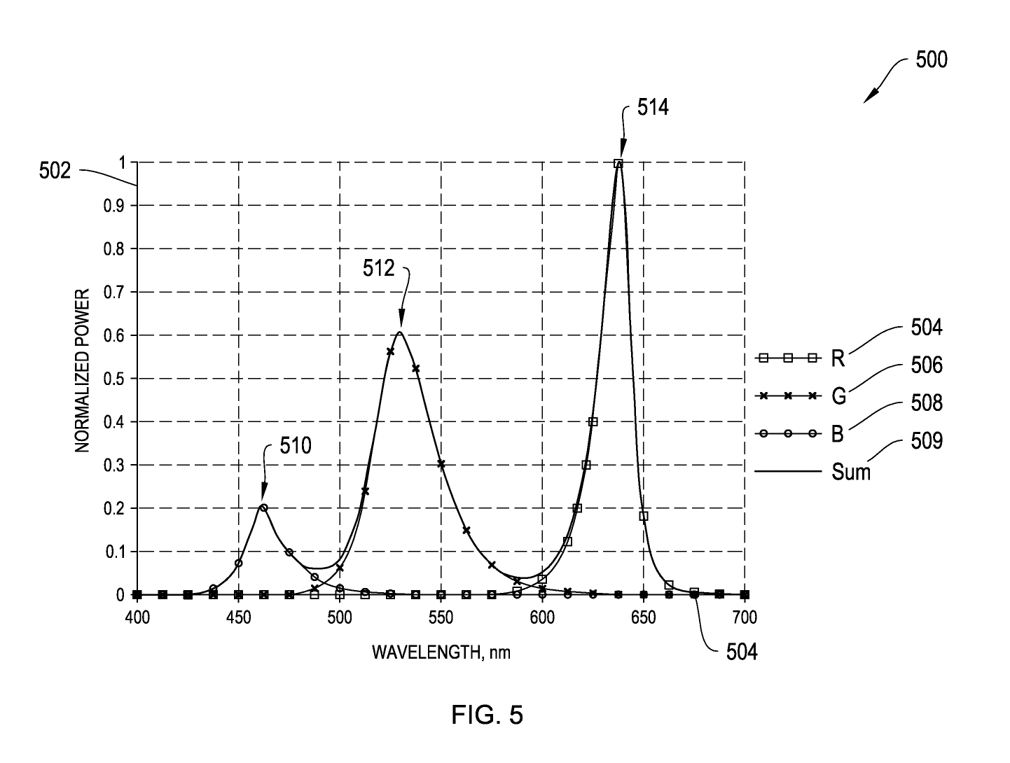

Thus, the film stack 402 has materials and thicknesses selected for reducing reflections from a light source. Optionally, the light source may be a composite light source. FIG. 5 is a graphical illustration of the wavelengths of light generated by a light source having plural different spectral components. In particular, FIG. 5 depicts a graph 500 of the normalized illumination spectrum of a composite light having a red component 504, a green component 506 and a blue component 508. In particular, FIG. 5 depicts a graph 500 that has an Y axis 502 that represents normalized power and an X axis 504 that represents wavelengths. The depicted spectrum has three peaks, a first peak 510 occurring at approximately 460 nm and representing the peak normalized power for the blue 508 component of the composite light source. Peak 512 represents the peak normalized power for the green component 506 of the composite light source and peak 514 represents the peak normalized power for the red 504 component of the composite light source. The dashed line 509 represents the sum of the power spectrums of the three discreet components—red 504, green 506 and blue 508—of the composite light source. As can be seen from FIG. 5, the light source has an uneven power distribution with three peaks located between about 450 and 650 nm of wavelength for the purpose of white balance. Other light sources may have one, two, four or some other number of peaks. The peaks may be located from 400 to 700, 800 or 900 nm or within some range that includes portions of the visible spectrum, and the peaks in the light source and the spectrum of the light source will vary depending upon the application being addressed and the resources available for the application being addressed. This power spectrum distribution is used together with the photopic luminosity function and the optical reflectivity of the thin film stack to calculate the photopically weighted reflectivity.

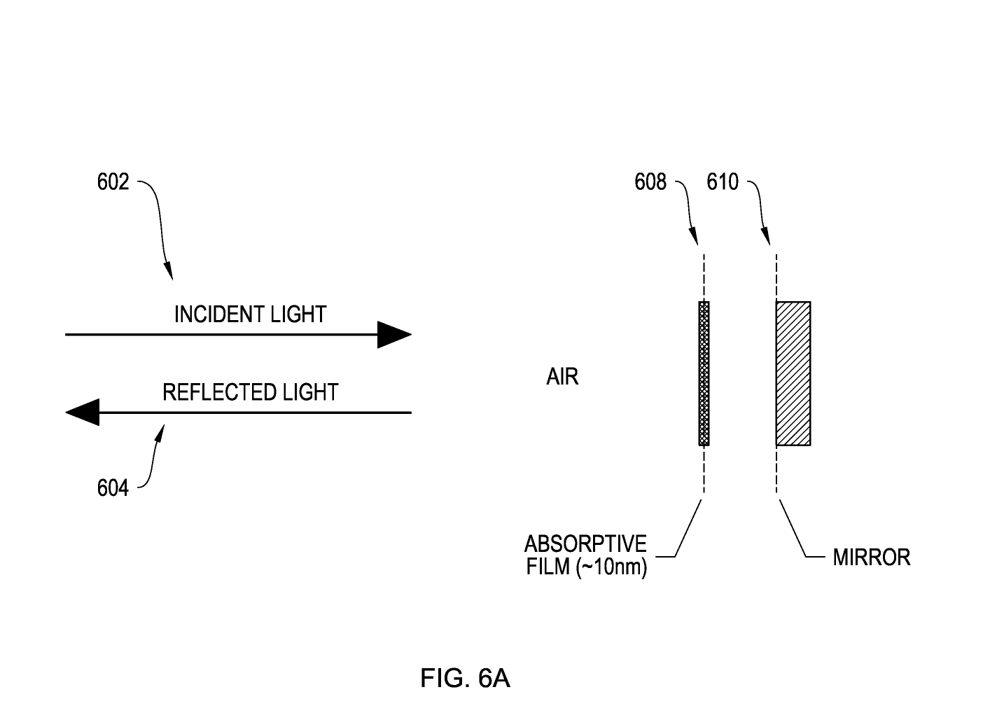

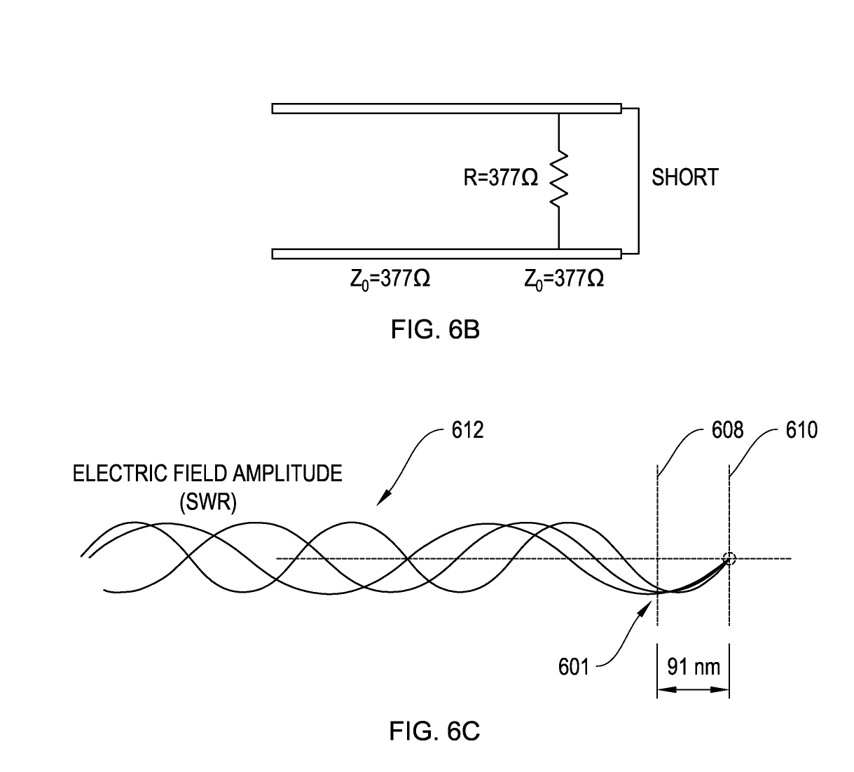

FIGS. 6A, 6B and 6C are pictorial representations of the reflection of light onto an interferometric absorbing structure, such as the film stack 402. In particular, FIG. 6A depicts incident light 602 directed toward an absorptive film 608 and a mirror 610. Additionally, FIG. 6A depicts reflected light 604 travelling back from mirror 610 and through the absorptive film 608. FIG. 6B illustrates a circuit model representing the power dissipation of light reflected from the mirror 610. When the impedance of the absorbing stack matches, typically by being substantially identical to, the impedance of the medium, in this case air (Zo=377Ω), of the incident light, it will have a reduced and, typically minimal, light reflection. FIG. 6C depicts pictorially the standing wave established by the interference between the incident wave and the reflection wave. Placing an absorbing material at the peak of the standing wave, e.g., location 601, allows energy, typically the greatest amount of energy, to be absorbed. The light energy is dissipated, typically through heat, via the stack and a reduced amount of light will be reflected. However, due to the dispersion of the absorbing material, that is the characteristic that the refractive index varies with wavelength, it is difficult to obtain impedance matching for all the wavelengths. A pair of high dispersion material (such as TiO₂) and low dispersion material (such as SiO₂) disposed on top of the absorbing layer can be used to establish the phase matching and reduce the reflection. It is also possible to use a single impedance matching layer with the proper dispersion characteristics to achieve good impedance matching.

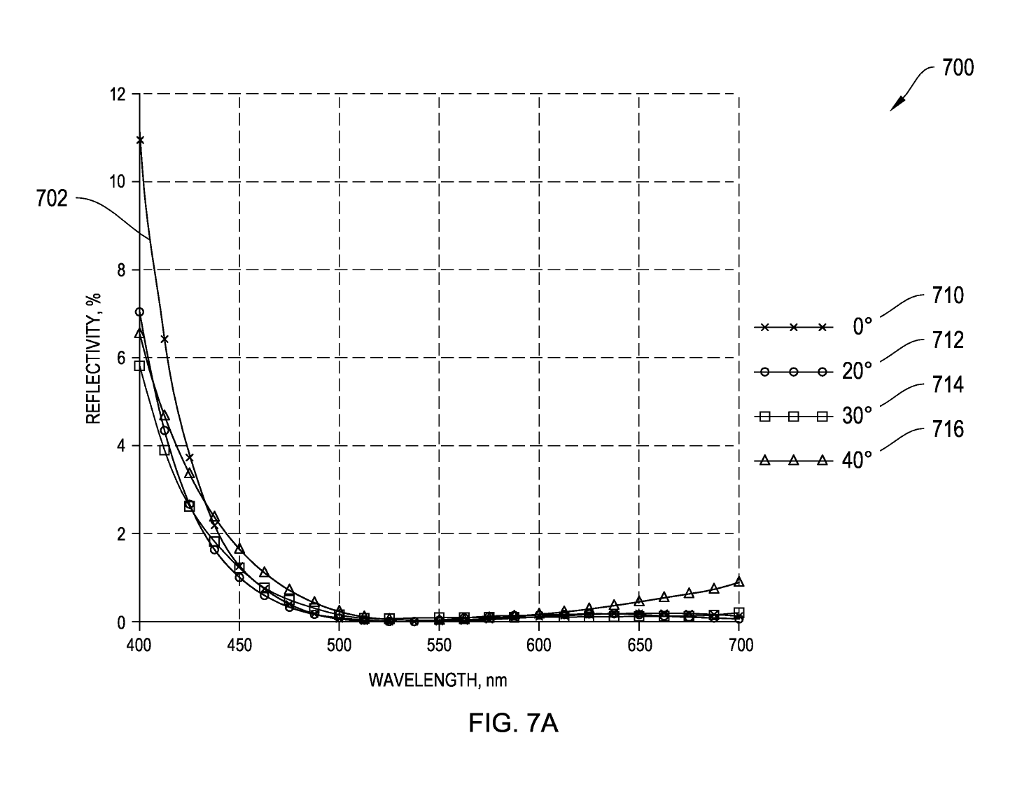

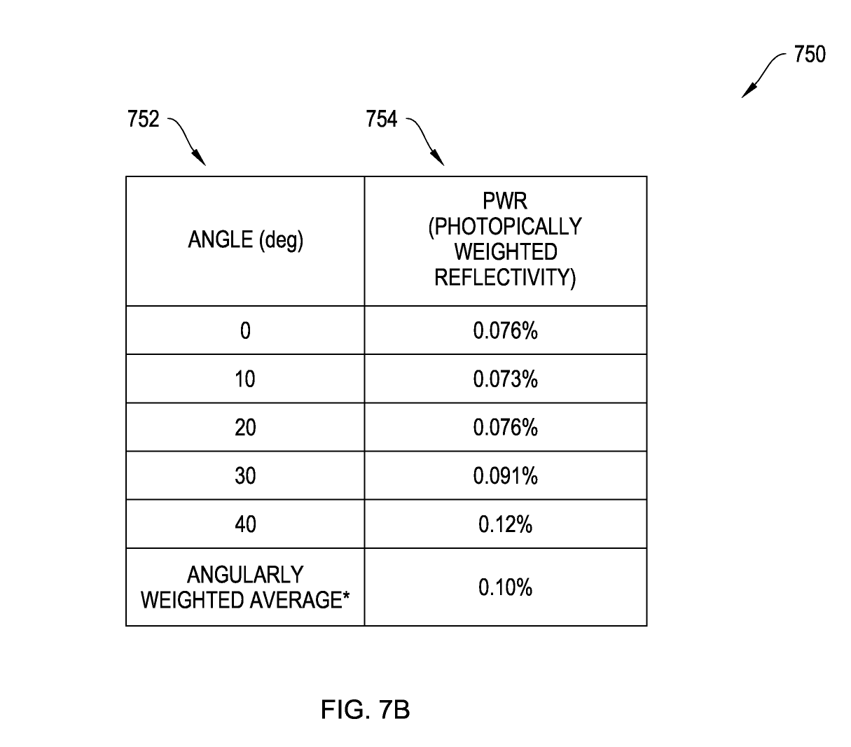

FIGS. 7A and 7B are graphical representations of the reflection characteristics of a film stack of the type shown in FIG. 4. FIGS. 7A and 7B present computer simulation data showing the performance of a thin film absorbing stack such as the stack 402 depicted in FIG. 4. In particular, FIG. 7A depicts a graphical representation of the reflectivity versus the wavelength of light incident on the film at different angles. In particular, FIG. 7a depicts a graph 700 that has a Y-axis 702 showing the percent reflectivity of light incident on the surface of a film at different angles. The X-axis depicts wavelengths, in nm, of light incident at different angles and reflected from the surface of the light absorbing film. The graph depicts four curves; a first curve 710 associated with light incident at an angle of 0°, a second curve 712 associated with light incident at 20°, a third curve 714 associated with light incident at 30° and a fourth curve 716 associated with light incident at 40°. The range of angles of incidence from 0° to 40° were selected, in this example, to model the behavior of light passing through a gap between a shutter and the substrate surface of a shutter assembly and reflecting from that substrate surface out of the display, as shown in FIG. 3 by light ray 321A. In any case, the graph 700 illustrates that reflectivity at all wavelengths of the power spectrum associated with the composite light source, such as the light source depicted in FIG. 5, remain below 2 percent of reflectivity. FIG. 7B depicts a table 750 that presents the photopically weighted reflectivity of the composite light at different angles of incidence. In particular, 7B depicts a table 750 that includes a first column 752 that lists angles of incidence and a second column 754 that gives associated photopically weighted reflectivity. As shown in the table, for angles of incidence set out in column 752 of 0°, 10°, 20°, 30° and 40°, the photopically weighted reflectivity remains below 15 hundredths of a percent for each angle of incidence and has an angular weighted average of about 10 hundredths of a percent.

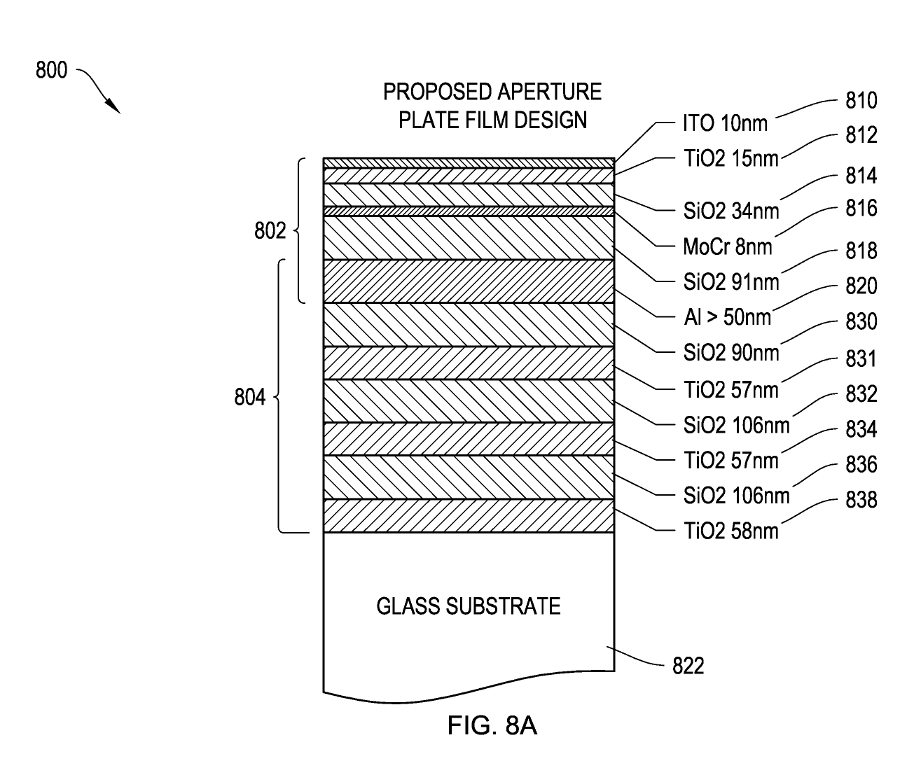

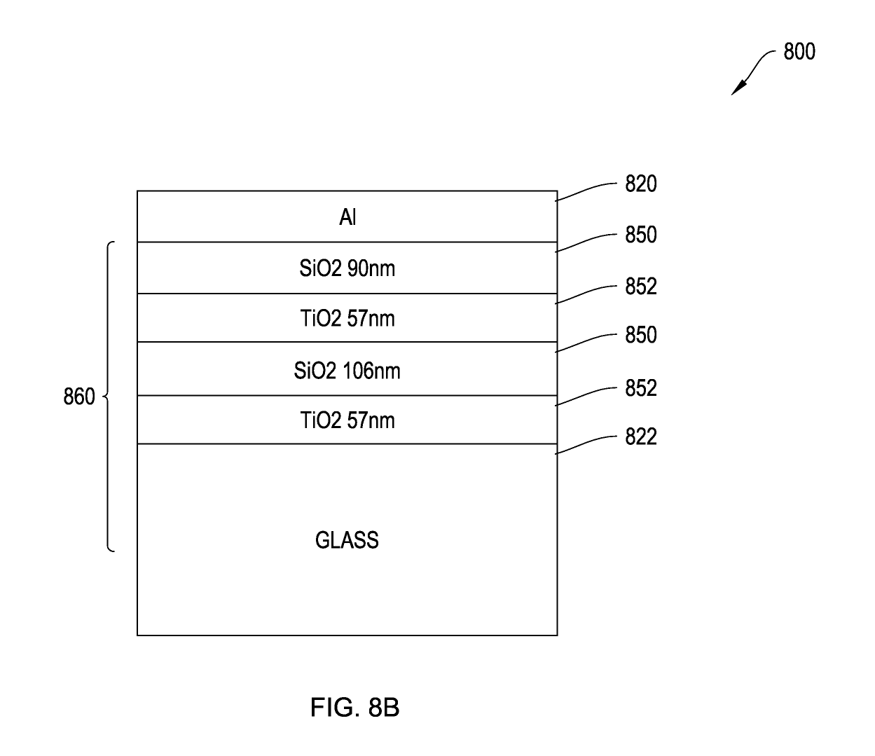

To achieve improved light recycling efficiency in the light guide of 316, high photopic reflectivity film stack is formed on the other side of the absorbing thin film stack 402 facing the light guide 316. FIGS. 8A and 8B are two examples of film stacks having high reflectivity. In particular, FIG. 8A depicts a film 800 that includes a light-absorbing film stack 802 positioned on a light-reflecting layer 820, typically a metal layer having a reflectance of greater than 70% and typically greater than 90% and a high-reflectivity film stack 804 disposed on an opposite side of the light-reflecting layer 820.

In particular, FIG. 8A depicts a thin film stack 800 that includes a light-absorbing stack 802, similar to the light-absorbing stack disclosed above. However, the stack 800 also includes a high reflectivity stack 804 that includes a reflective material 820, in this case aluminum, at a thickness of about 50 nm or greater, and one or more pairs of dielectric films including a first material with a first refractive index and a second material with a second, different refractive index. The stack 804 may be formed as a thin film Bragg reflector having a multilayer stack of alternating materials of higher and lower refractive index films, the films being typically about one quarter wavelength thick.

In the example of FIG. 8A, the first and second materials are SiO₂ and TiO₂ and SiO₂ has an average refractive index over the visible spectrum, n, of about 1.5 and TiO₂ has an average refractive index over the visible spectrum, n, of about 2.5 at the wavelength of 500 nm. A person of ordinary skill will readily understand that the exact value of the refractive index varies with the thin film deposition condition; and the thin film design, such as thickness and purity of material, will be adjusted accordingly depending on the design parameters. As further depicted by FIG. 8A, the different pairs of dielectric material have different thicknesses wherein the thicknesses are selected to establish constructive interference that provides for substantial reflectivity of light at a selected range of wavelengths and having a selected range of angles of incidence. The layers in reflective stack 804 are selected to achieve increased and, preferably maximum, photopically weighted reflectivity based on the power spectrum of the light source and the angular distribution of the illumination light on the high reflectivity stack 804. To this end, FIG. 8A depicts a thin aluminum layer having three pairs of TiO₂/SiO₂ layers joined with the aluminum layer.

As noted above, layering the materials in the high reflectivity stack 804 to have selected thicknesses, and optionally doing so in multiple pairs, introduces a selected phase shift to light passing through the high reflectivity stack 804. For the high reflectivity stack 804 to interferometrically achieve high reflectivity, the phase shift is selected to cause constructive interference among the lights reflected from the layers. In some implementations, the thicknesses of the layers is selected to be about quarterwave thickness to achieve a constructive interference that provides high reflectivity for light within the power spectrum of the light source and with the angular distribution of the light in the light source, which is directly incident on the high reflectivity stack 804.

The Table 2 below presents example film thicknesses given in nm for one high reflectivity stack 804.

TABLE 2

| | | Thickness, |
|---|---|---|
| Layer # | material | nm |
| 1 | Al | >50 |
| 2 | SiO2 | 89.9 |
| 3 | TiO2 | 56.7 |
| 4 | SiO2 | 106 |
| 5 | TiO2 | 57.0 |
| 6 | SiO2 | 106 |
| 7 | TiO2 | 58.0 |

Other materials that have a high refractive index, such as ZrO₂ and Si₃N₄ can be used to replace TiO₂. Likewise, other materials that have a low refractive index, such as MgF₂ and Al₂O₃ can be used to replace SiO₂. As a person having ordinary skill in the art will readily understand, the thickness of the layers will need to be re-optimized to achieve the maximum reflectivity, depending on the design parameters.

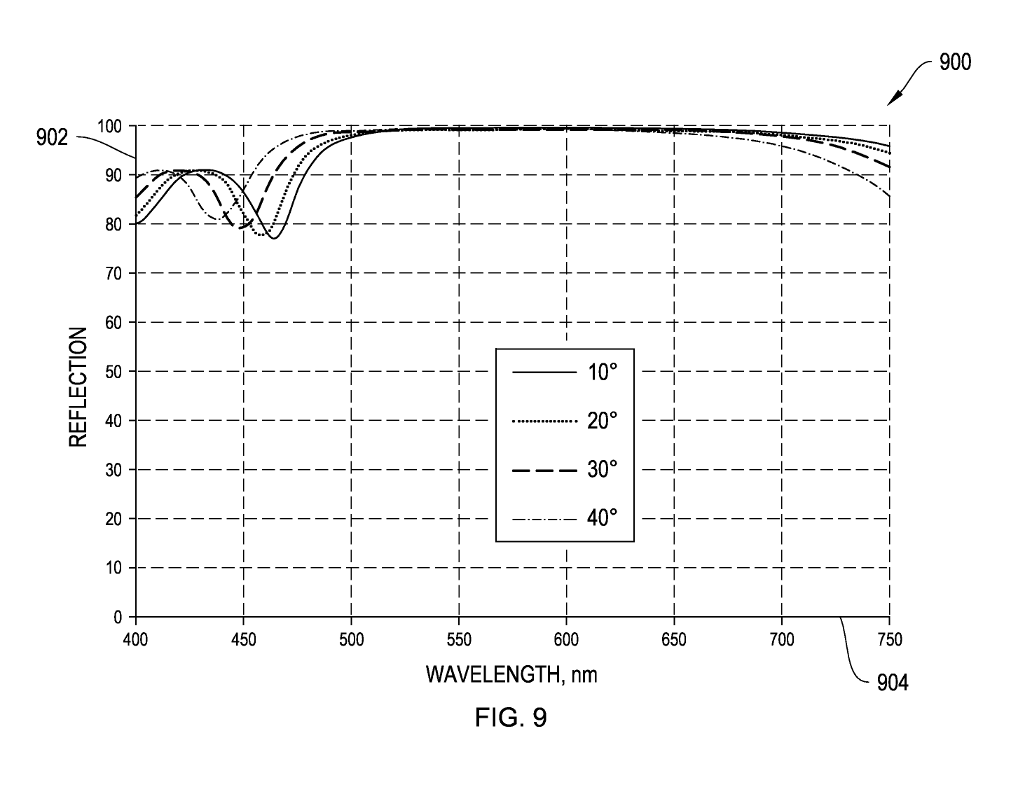

FIG. 9 is a graphical illustration of the angular distribution of a high reflectivity film such as the film of FIG. 8A. In particular, FIG. 9 depicts a graph 900 that includes a Y-axis representing calculated reflectivity and an X-axis representing the wavelength. Reflectivity for four angles of light incidence, 0°, 20°, 30° and 40° are shown. Because the angle of light incident against the high reflectivity film stack is confined smaller than 50°, and most of the light having an angle smaller than 40°, these curves show that the stack 804 provides a high level of reflectivity for light incident on the stack 804. The curves show, particularly, that the reflectivity is high for the spectrum having a high photopic luminosity value (e.g., the reflectivity is greater than about 99% at 550 nm−the peak of photopic luminosity function). As such, the photopically weight reflectivity is greater than 97% for all the angles of incidence.

The aluminum layer is a thin layer of 50 nm or thicker. There is a SiO₂/TiO₂ pair of 89.9/56.7 nm, a second SiO₂/TiO₂ pair of 106.0/57.0 nm and a third SiO₂/TiO₂ pair of 106.0/58.0 nm. Tolerances can vary as described above with the absorption film stack 402 of FIG. 4. For example, in other implementations the thickness of the reflecting metal layer 820 may be between 15 and 150 nm thick, or between 35 and 65 nm thick, or between 49 and 51 nm thick. The thickness of this layer 820 may vary to address the application, the type of material employed as a reflecting material, which in some implementations is metal, but in other implementations may be a metal composite or other material, and as a result in variations of the employed deposition techniques. The thicknesses of the SiO₂/TiO₂ pairs may vary in other implementations and in some implementations the thicknesses of the SiO₂ may vary from 30 to 300 nm and in other implementations may vary from 80 to 100 nm and in some other implementations may vary from 87 to 91 nm. The paired layer of TiO₂ respectively may vary from 15 to 150 nm and in other implementations may vary from 40 to 70 nm and in some other implementations may vary from 55 to 59 nm. These thin film layers may be fabricated through deposition techniques such as physical vapor deposition (PVD, e.g., sputtering), plasma-enhanced chemical vapor deposition (PECVD), thermal chemical vapor deposition (thermal CVD), spin-coating or other semiconductor manufacturing process.

Although the above example employs three pairs of SiO₂/TiO₂ layers, in other implementations, two pairs of SiO₂/TiO₂ layers or one pair may be used. In these alternate implementations, a fewer number of layers may be employed and the reduced number of pairs will result in reduced reflectivity specified for the application. One such implementation is depicted in FIG. 8B. As shown in FIG. 8B, the high reflectivity stack 862 has two pairs of SiO2/TiO2 layers 850 and 852 respectively. Both pairs are layered over the reflective layer of aluminum, which is greater than 50.0 nm, thereby providing high reflectivity with one less pair of materials, but the reflectivity is generally smaller than that with three pairs of TiO₂/SiO₂ layers.

Other implementations may be used to provide a high reflectivity surface on the opposite side of the light absorbing surface described above and the implementation used will depend upon the application being addressed and all such implementations fall within the scope of the systems and methods described herein.

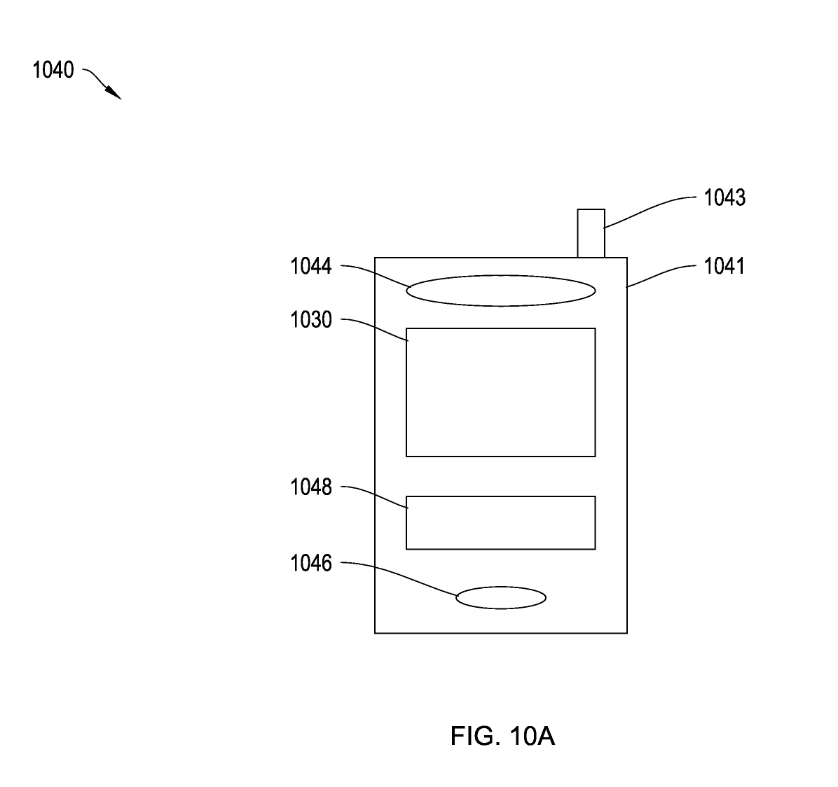

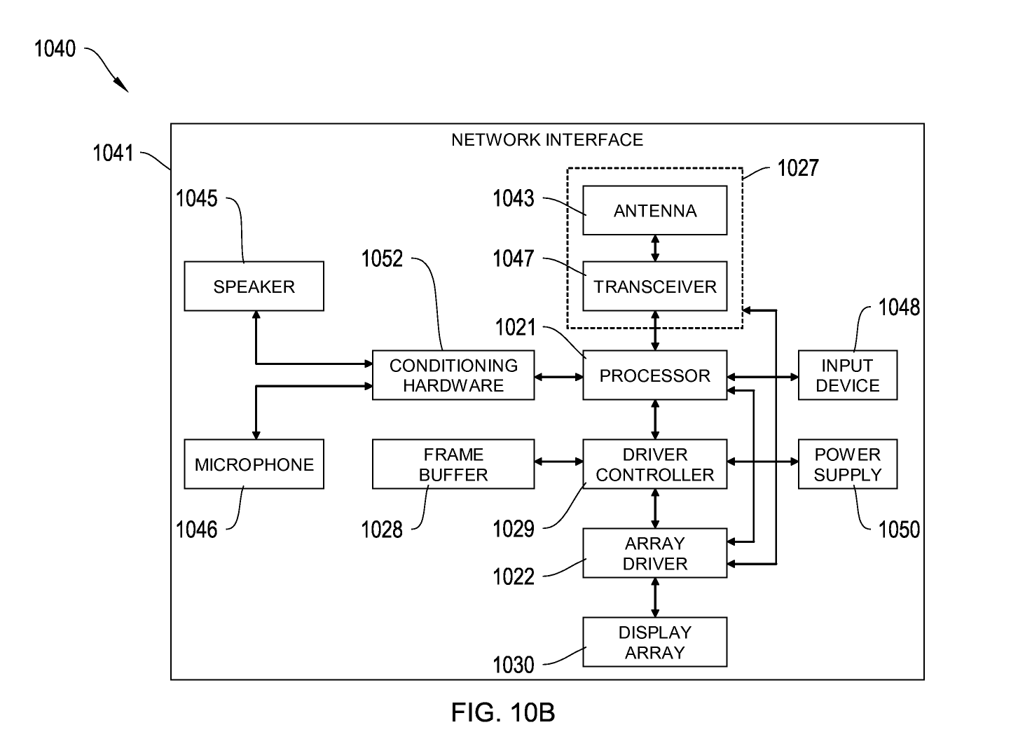

The displays described above can be used in computer systems, cellular phones, wireless devices, e-readers, netbooks, notebooks, tablets or any other device that includes a visual display. FIGS. 10A and 10B are examples of a display device and controller of the type suitable for use with the displays described herein. In particular, FIGS. 10A and 10B are system block diagrams illustrating one such display device 1040 that may include a display as described herein. The display device 1040 can be, for example, a smart phone, a cellular or mobile telephone. However, the same components of the display device 1040 or slight variations thereof are also illustrative of various types of display devices such as televisions, computers, tablets, e-readers, hand-held devices and portable media devices. The display device 1040 includes a housing 1041, a display 1030, an antenna 1043, a speaker 1045, an input device 1048 and a microphone 1046. The housing 1041 can be formed from any of a variety of manufacturing processes, including injection molding, and vacuum forming. In addition, the housing 1041 may be made from any of a variety of materials, including, but not limited to: plastic, metal, glass, rubber and ceramic, or a combination thereof. The housing 1041 can include removable portions (not shown) that may be interchanged with other removable portions of different color, or containing different logos, pictures, or symbols.

The display 1030 may be any of a variety of displays, including a bi-stable or analog display, as described herein. The display 1030 also can be configured to include a flat-panel display, such as plasma, EL, OLED, STN LCD, or TFT LCD, or a non-flat-panel display, such as a CRT or other tube device. In addition, the display 1030 can include an light modulator-based display, as described herein.

The components of the display device 1040 are schematically illustrated in FIG. 10A. The display device 1040 includes a housing 1041 and can include additional components at least partially enclosed therein. For example, the display device 1040 includes a network interface 1027 that includes an antenna 1043 which can be coupled to a transceiver 1047. The network interface 1027 may be a source for image data that could be displayed on the display device 1040. Accordingly, the network interface 1027 is one example of an image source module, but the processor 1021 and the input device 1048 also may serve as an image source module. The transceiver 1047 is connected to a processor 1021, which is connected to conditioning hardware 1052. The conditioning hardware 1052 may be configured to condition a signal (such as filter or otherwise manipulate a signal). The conditioning hardware 1052 can be connected to a speaker 1045 and a microphone 1046. The processor 1021 also can be connected to an input device 1048 and a driver controller 1029. The driver controller 1029 can be coupled to a frame buffer 1028, and to an array driver 1022, which in turn can be coupled to a display array 1030. One or more elements in the display device 1040, including elements not specifically depicted in FIG. 10A, can be configured to function as a memory device and be configured to communicate with the processor 1021. In some implementations, a power supply 1050 can provide power to substantially all components in the particular display device 1040 design.

The network interface 1027 includes the antenna 1043 and the transceiver 1047 so that the display device 1040 can communicate with one or more devices over a network. The network interface 1027 also may have some processing capabilities to relieve, for example, data processing requirements of the processor 1021. The antenna 1043 can transmit and receive signals. In some implementations, the antenna 1043 transmits and receives RF signals according to the IEEE 16.11 standard, including IEEE 16.11(a), (b), or (g), or the IEEE 802.11 standard, including IEEE 802.11a, b, g, n, and further implementations thereof. In some other implementations, the antenna 1043 transmits and receives RF signals according to the Bluetooth® standard. In the case of a cellular telephone, the antenna 1043 can be designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G, 4G or 5G technology. The transceiver 1047 can pre-process the signals received from the antenna 1043 so that they may be received by and further manipulated by the processor 1021. The transceiver 1047 also can process signals received from the processor 1021 so that they may be transmitted from the display device 1040 via the antenna 1043.

In some implementations, the transceiver 1047 can be replaced by a receiver. In addition, in some implementations, the network interface 1027 can be replaced by an image source, which can store or generate image data to be sent to the processor 1021. The processor 1021 can control the overall operation of the display device 1040. The processor 1021 receives data, such as compressed image data from the network interface 1027 or an image source, and processes the data into raw image data or into a format that can be readily processed into raw image data. The processor 1021 can send the processed data to the driver controller 1029 or to the frame buffer 1028 for storage. Raw data typically refers to information that identifies the image characteristics at each location within an image. For example, such image characteristics can include color, saturation and gray-scale level.

The processor 1021 can include a microcontroller, CPU, or logic unit to control operation of the display device 1040. The conditioning hardware 1052 may include amplifiers and filters for transmitting signals to the speaker 1045, and for receiving signals from the microphone 1046. The conditioning hardware 1052 may be discrete components within the display device 1040, or may be incorporated within the processor 1021 or other components.

The driver controller 1029 can take the raw image data generated by the processor 1021 either directly from the processor 1021 or from the frame buffer 1028 and can re-format the raw image data appropriately for high speed transmission to the array driver 1022. In some implementations, the driver controller 1029 can re-format the raw image data into a data flow having a raster-like format, such that it has a time order suitable for scanning across the display 1030. Then the driver controller 1029 sends the formatted information to the array driver 1022. Although a driver controller 1029, such as an LCD controller, is often associated with the system processor 1021 as a stand-alone Integrated Circuit (IC), such controllers may be implemented in many ways. For example, controllers may be embedded in the processor 1021 as hardware, embedded in the processor 1021 as software, or fully integrated in hardware with the array driver 1022.

The array driver 1022 can receive the formatted information from the driver controller 1029 and can re-format the video data into a parallel set of waveforms that are applied many times per second to the hundreds, and sometimes thousands (or more), of leads coming from the display's x-y matrix of display elements.

In some implementations, the driver controller 1029, the array driver 1022, and the display 1030 are appropriate for any of the types of displays described herein. For example, the driver controller 1029 can be a conventional display controller or a bi-stable display controller (such as a light modulator display element controller). Additionally, the array driver 1022 can be a conventional driver or a bi-stable display driver (such as a light modulator display element driver). Moreover, the display array 1030 can be a conventional display array or a bi-stable display array (such as a display including an array of light modulator display elements). In some implementations, the driver controller 1029 can be integrated with the array driver 1022. Such an implementation can be useful in highly integrated systems, for example, mobile phones, portable-electronic devices, watches or small-area displays.

In some implementations, the input device 1048 can be configured to allow, for example, a user to control the operation of the display device 1040. The input device 1048 can include a keypad, such as a QWERTY keyboard or a telephone keypad, a button, a switch, a rocker, a touch-sensitive screen, a touch-sensitive screen integrated with the display array 1030, or a pressure- or heat-sensitive membrane. The microphone 1046 can be configured as an input device for the display device 1040. In some implementations, voice commands through the microphone 1046 can be used for controlling operations of the display device 1040.

The power supply 1050 can include a variety of energy storage devices. For example, the power supply 1050 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 1050 also can be a renewable energy source, a capacitor, or a solar cell, including a plastic solar cell or solar-cell paint. The power supply 1050 also can be configured to receive power from a wall outlet.

In some implementations, control programmability resides in the driver controller 1029 which can be located in several places in the electronic display system. In some other implementations, control programmability resides in the array driver 1022. The above-described optimization may be implemented in any number of hardware and/or software components and in various configurations.

As used herein, a phrase referring to “at least one of” a list of items refers to any combination of those items, including single members. As an example, “at least one of: a, b, or c” is intended to cover: a, b, c, a-b, a-c, b-c, and a-b-c.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of, e.g., a display element as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, a person having ordinary skill in the art will readily recognize that such operations need not be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A device, comprising
a substrate layer disposed proximate a light source and having
an aperture to allow light to pass through the substrate layer, and
an absorption film stack including:
a layer of light reflecting material,
a layer of light absorbing material disposed on the layer of light reflecting material and being spaced a fixed distance from the layer of light reflecting material, and
an interferometric absorption film stack, including:
a layer of a dielectric material of a first refractive index, and a layer of dielectric material of a second refractive index,
the thicknesses of the layers of dielectric material being selected to cause light reflected from the interferometric absorption film stack to interfere with light incident on the interferometric absorption film stack and have an interference standing wave with a peak amplitude occurring at the layer of light absorbing material.

2. The device of claim 1, wherein the layer of dielectric material of a first refractive index, and the layer of dielectric material of a second refractive index are selected to reduce reflection of light incident at an angle between 0° and 50° to an axis normal to the surface of the interferometric absorption film stack.

3. The device of claim 1, wherein the fixed distance arranges the layer of absorbing material at a location of a substantially peak amplitude of the interference standing wave in the absorption film stack.

4. The device of claim 1, further including a spacing layer of transmissive material disposed between the layer of light reflecting material and the layer of absorbing material.

5. The device of claim 4, wherein the spacing layer has a thickness for spacing the absorbing layer the fixed distance from the layer of light reflecting material.

6. The device of claim 1, wherein the layer of light reflecting material includes a layer of metal having a reflectance greater than 70% through a spectrum for visible light.

7. The device of claim 1, wherein the layer of light reflecting material includes a layer selected from the group of aluminum (Al), chromium (Cr), molybdenum (Mo), nickel (Ni), tantalum (Ta) and silver (Ag).

8. The device of claim 1, further comprising a transparent conductive layer disposed on the interferometric absorption film stack.

9. The device of claim 1, further comprising a reflective film disposed on a surface of the layer of light reflecting material opposite the light absorbing material.

10. The device of claim 9, wherein the reflective film includes a dielectric thin film stack having a first material with a first refractive index and a second material with a second refractive index, the first material and the second material having a respective thickness of about a quarter wavelength of light from the light source.

11. The device of claim 1, further comprising a layer of fluid disposed over the interferometric absorption film stack.

12. The device of claim 1, wherein the light source includes a light source or plurality of light sources transmitting light at different wavelength spectrums centered respectively at colors red, green and blue (RGB).

13. The device of claim 12, wherein the layer of dielectric material of a first refractive index has a thickness of about 34 nm and the layer of dielectric material of a second refractive index has a thickness of about 15 nm.

14. The device of claim 1, wherein the layer of dielectric material of a first refractive index includes silicon dioxide (SiO₂) and the layer of dielectric material of a second refractive index includes titanium dioxide (TiO₂).

15. The device of claim 1, wherein the substrate layer includes a movable shutter for blocking or passing light from the aperture.

16. The devices of claim 1, further comprising:
a processor that is configured to communicate with the display, the processor being configured to process image data; and
a memory device that is configured to communicate with the processor.

17. The device of claim 16, further comprising:
a driver circuit configured to send at least one signal to the display; and
a controller configured to send at least a portion of the image data to the driver circuit.

18. The device of claim 16, further comprising:
an image source module configured to send the image data to the processor, wherein the image source module comprises at least one of a receiver, transceiver, and transmitter.

19. The device of claim 16, further comprising:
an input device configured to receive input data and to communicate the input data to the processor.

20. A method of manufacturing, comprising:
providing a layer of light reflecting material, and
forming over the layer of light reflecting material, a light absorbing film having:
a layer of light absorbing material, and
a first layer of material with a first index of refraction and a first thickness of about 25 to 40 nm and a second layer of material with a second index of refraction and a second thickness of about 10 nm to 20 nm, the respective thicknesses of the first and second layers being selected to provide interferometric attenuation of light within a selected range of wavelengths and at an angle of incidence more than about 30° to an axis normal to the absorbing film.

21. The method of claim 20, further comprising arranging the layer of absorbing material at a location of a substantially peak amplitude of a standing wave formed by the interferometric attenuation.

22. The method of claim 20, further including:
providing a spacing layer of transmissive material between the light reflecting layer and the layer of absorbing material and having a thickness selected to space the layer of absorbing material from the light reflecting layer about a quarter wavelength of light reflected from the light reflecting layer.

23. The method of claim 20, further comprising:
forming between the substrate and the light absorbing film, a film stack having:
a first material with a first refractive index and a second material with a second refractive index, the first material and the second material having respective thicknesses of about a quarter wavelength of light to be reflected.

24. The method of claim 23, wherein the first material has a thickness of between about 80 nm to about 110 nm and the second material has a thickness of between about 50 nm and about 65 nm.

25. The method of claim 23, wherein the first material includes silicon dioxide (SiO₂) and the second material includes titanium dioxide (TiO₂).

26. The method of claim 20, wherein the layer of light reflecting material is a layer of metal.

27. The method of claim 20, wherein forming the first layer of material includes,
depositing the first layer using a process selected from the group consisting of chemical vapor deposition, physical vapor deposition, plasma-enhanced chemical vapor deposition, thermal chemical vapor deposition (thermal CVD), and spin-coating.

28. The method of claim 20, wherein providing a layer of light reflecting material includes
providing a shutter movable from a first position to a second position and having a surface with a layer of light reflecting material.

29. The method of claim 28, wherein forming the light absorbing film, includes
forming the light absorbing film over the layer of light reflecting material of the shutter.

30. A thin film stack, comprising
a substrate layer having an aperture to allow light to pass through the substrate layer and being disposed proximate a light source of a first wavelength, and including
a layer of light reflecting material having a first side and a second side,
an interferometric absorption stack disposed on the second side of the layer of light reflecting material and having two layers of dielectric material with thicknesses and refractive indices selected to reduce a reflectivity of light incident at angles 0° to 50° and propagating at the first wavelength, and
a high reflectance stack disposed on the first side of the layer of light reflecting material and having one or more than one paired layers of dielectric material with thicknesses and refractive indices selected to achieve photopically weighted reflectivity of greater than 90% for light incident at angles between 0° to 50° and propagating at the first wavelength.

31. The thin film stack of claim 30, wherein the substrate layer includes a layer of photopically transparent material.

32. The thin film stack of claim 30, further including
a shutter disposed proximate the aperture and movable across the aperture for passing and blocking light passing through the aperture to provide a pixel within an image.

33. The thin film stack of claim 30, wherein the light source includes a plurality of light sources generating light at different respective wavelengths.

34. The thin film stack of claim 33, wherein the interferometric absorption stack includes two layers of dielectric material with thicknesses and refractive indices selected to reduce a photopically weighted reflectivity of light propagating at the different respective wavelengths.

35. The display of claim 33, wherein the high reflectance stack includes one or more paired layers of dielectric material with thicknesses and refractive indices selected to achieve a photopically weighted reflectivity of greater than 95% for light propagating at the different respective wavelengths.
